(19) United States
(12) Patent Application Publication
(10) Pub. No.: US 2019/0378582 A1
(43) Pub. Date: Dec. 12, 2019

(54) METHOD FOR PERFORMING PROGRAM INHIBIT OPERATION WITH CELL DISTURBANCE ALLEVIATION, MEMORY DEVICE AND CONTROLLER

(71) Applicant: MACRONIX INTERNATIONAL CO., LTD., Hsinchu (TW)

(72) Inventors: Tao-Yuan LIN, Taipei City (TW); I-Chen YANG, Miaoli County (TW); Yao-Wen CHANG, Zhubei City (TW)

(21) Appl. No.: 16/003,189

(22) Filed: Jun. 8, 2018

(51) Int. Cl. G11C 16/34; G11C 16/22; G11C 16/04

(52) U.S. Cl. CPC G11C 16/3427; G11C 16/22; G11C 16/08; G11C 16/0408; G11C 16/0466; G11C 16/0483

(57) ABSTRACT

A method for performing a program inhibit operation with cell disturbance alleviation, a memory device and a controller are provided. The method includes the following steps. A verify operation is performed on a cell string of a cell array. A power pulse is applied on the cell string. The program inhibit operation is performed on the cell string. The step of applying the power pulse is performed before the step of performing the program inhibit operation.

### TECHNICAL FIELD

The disclosure relates in general to an operation method, a memory device and a controller, and more particularly to a method for performing a program inhibit operation with cell disturbance alleviation, a memory device and a controller.

### BACKGROUND

Along with the development of memory technology, various memories are invented. Each cell in the memory can be programed or erased to record data as “0” or “1,” For example, NAND memory is programmed via Fowler-Nordheim tunneling (FN-tunneling). When some cells are programmed via hot-electrons, other cells are performed the program inhibit operation to prevent from being programming via the FN-tunneling. For example, the channel potential is increased to reduce the voltage difference between the program voltage of the word line and the channel. However, when some of the cells are performed the program inhibit operation, a hot-electrons environment is created in some programming pattern, and the hot-electrons mode disturbance is happened during the program inhibit operation.

### SUMMARY

The disclosure is directed to a method of a method for performing a program inhibit operation with cell disturbance alleviation, a memory device and a controller. A power pulse is applied before performing the program inhibit operation, such that the down-coupling phenomenon could be suppressed. Because the down-coupling phenomenon is suppressed, the channel potential waveform is stable during the program inhibit operation without inducing any hot electron disturbance on the cells.

According to one embodiment, a method for performing a program inhibit operation is provided. The method includes the following steps. A verify operation is performed on a cell string of a cell array. A power pulse is applied on the cell string. The program inhibit operation is performed on the cell string. The step of applying the power pulse is performed before the step of performing the program inhibit operation.

According to another embodiment, a memory device is provided. The memory device includes a cell array, a word line decoder, a bit line decoder and a controller. The word line decoder is connected to a plurality of word lines of the cell array. The bit line decoder is connected to a plurality of bit lines of the cell array. The controller is connected to the word line decoder and the bit line decoder for performing a verify operation on a cell string of the cell array, applying a power pulse on the cell string, and performing a program inhibit operation on the cell string. The controller applies the power pulse before the program inhibit operation is performed.

According to an alternative embodiment, a controller is provided. The controller is connected to a word line decoder and a bit line decoder. The word line decoder is connected to a plurality of word lines of a cell array. The bit line decoder is connected to a plurality of bit lines of the cell array. The controller is used for performing a verify operation on a cell string of the cell array, applying a power pulse on the cell string, and performing a program inhibit operation on the cell string. The controller applies the power pulse before the program inhibit operation is performed.

### BRIEF DESCRIPTION OF THE DRAWINGS

FIG. 1 shows a memory device.

FIG. 2 shows a cell string of a cell array.

FIG. 3 shows a flowchart of a method for performing a program inhibit operation.

FIG. 4 illustrates the waveforms of the word line voltage, the pass voltage, the power voltage, the string select line voltage and the bit line voltage.

FIGS. 5A to 5D illustrate a plurality of channel potential waveforms in the cell string.

FIG. 6 shows an E-trapped charge pattern of the cell coupled to the word line which is injected the transient current.

FIG. 7 shows a flowchart of a method for performing the program inhibit operation with cell disturbance alleviation.

FIG. 8 illustrates the waveforms of the word line voltage, the pass voltage, the power voltage, the string select line voltage and the bit line voltage.

FIG. 9 illustrates two channel potential waveforms in the cell string at two time points respectively.

FIG. 10 illustrates a comparison between two channel potential waveforms of the cell string at two time points.

FIG. 11 illustrates a comparison between an E-trapped charge pattern of the cell coupled to the word line which is not injected the transient current and the E-trapped charge pattern of FIG. 6.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

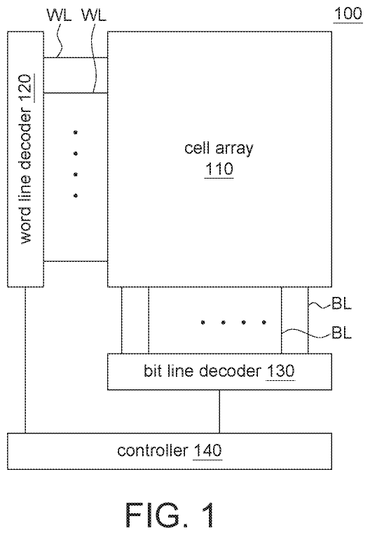

Please refer to FIG. 1, a memory device 100 is shown. The memory device 100 includes a cell array 110, a word line decoder 120, a bit line decoder 130 and a controller 140. The cell array 110 may be a 3D NAND memory, a floating gate memory, a nitride-trapping memory, a gate-all-around (GAA) memory or a vertical channel memory. The word line decoder 120 is connected to a plurality of word lines WL of the cell array 110 and the bit line decoder 130 is connected to a plurality of bit lines BL of the cell array 110.

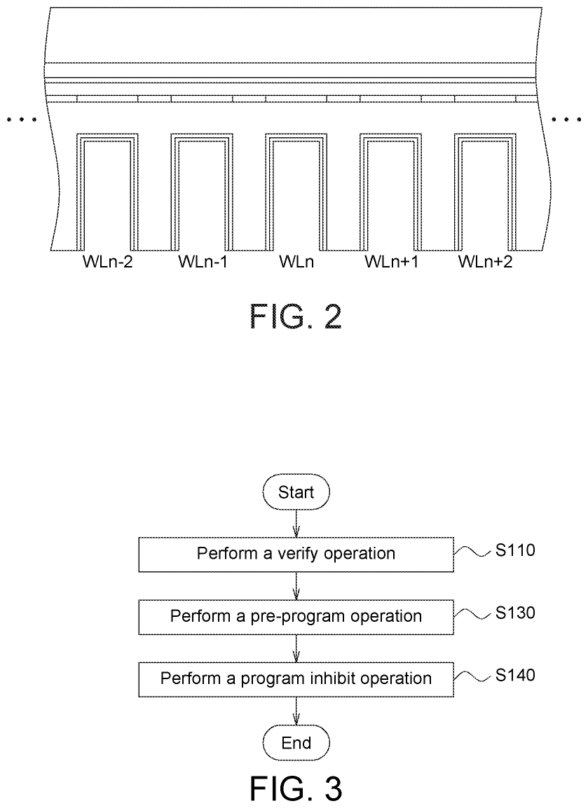

Please refer to FIG. 2, one cell string 111 of the cell array 110 is shown. The cell string 111 is connected to word lines WLn−2, WLn−1, WLn, WLn+1, WLn+2. When the word line WLn is applied a program voltage, a program inhibit operation is needed to be performed on the cells in the cell string 111 which are not needed to be programed.

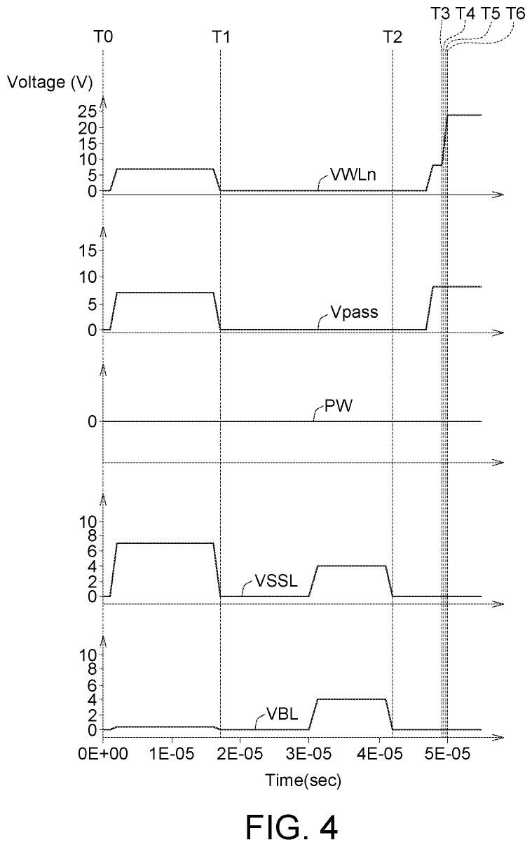

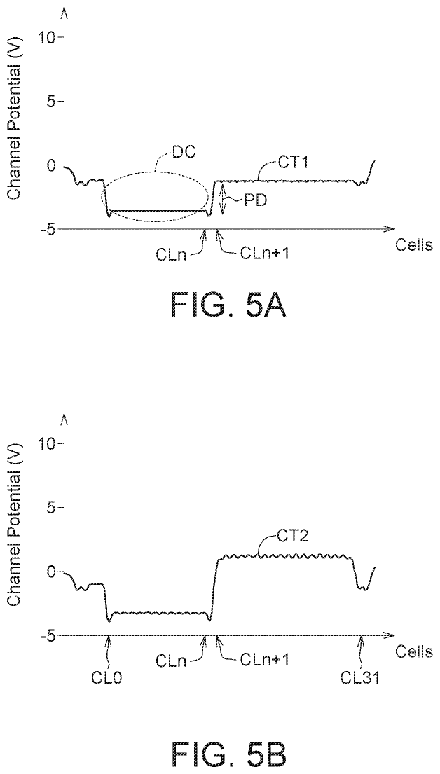

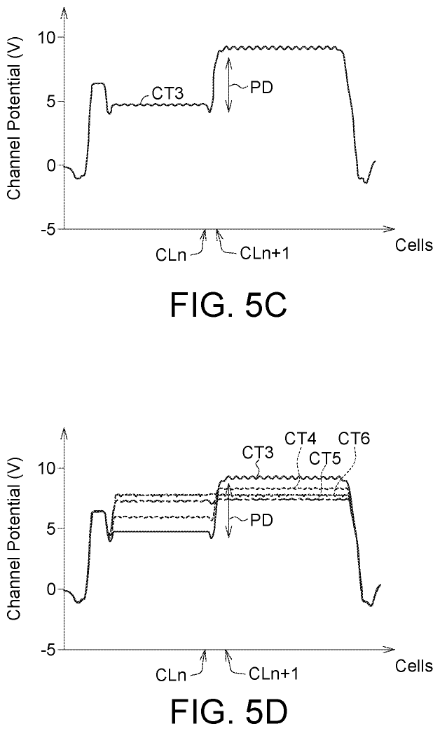

Please refer to FIG. 3 to FIG. 5D. FIG. 3 shows a flowchart of a method for performing the program inhibit operation, FIG. 4 illustrates the waveforms of the word line voltage VWLn, the pass voltage Vpass, the power voltage PW, the string select line voltage VSSL and the bit line voltage VBL, and FIGS. 5A to 5D illustrate the channel potential waveforms CT1 to CT6 in the cell string 111. In step S110, the controller 140 performs a verify operation on the cell string 111 from the time point T0 to the time point T1. In the verify operation, the word line voltage VWLn is increased to be 7V, the pass voltage Vpass is increased to be 7V, the power voltage PW is kept at 0V, the string select line voltage VSSL is increased to be 7V and the bit line voltage VBL is increased to be 0.6V. Refer to FIG. 5A, which illustrates the channel potential waveform CT1 of the cell string 111 at the time point T1. As the verify operation is just finished, the cell CLn coupled to the word line WLn is turned off and its channel potential falls to −4V due to the down-coupling phenomenon DC. There would be some channel potential difference PD between the cell CLn and the cell CLn+1 coupled to the word line WLn+1.

Next, in step S130, the controller 140 performs a pre-program operation on the cell string 111. In the pre-program operation, the word line voltage VWLn is kept at 0V, the pass voltage Vpass is kept at 0V, the power voltage PW is kept at 0V, the string select line voltage VSSL is increased to be 4V and the bit line voltage VBL is increased to be 4V. Refer to FIG. 56, which illustrates the channel potential waveform CT2 of the cell string 111 at the time point T2. During the charging of the string select line voltage VSSL and the bit line voltage VBL, the cells CLn+1 to CL31 coupled to the word lines WLn+1 to WL31 are pre-charged. Instead, the cells CL0 to CLn−1 coupled to the word lines WL0 to WLn−1 remain unchanged because the cell CLn−1 isolates the upper channel.

In step S140, the controller 140 performs a program inhibit operation on the cell string 111. At the beginning of the pre-program operation (time point T3), the word line voltage VWLn is increased to be 8V, the pass voltage Vpass is increased to be 8V, the power voltage PW is kept at 0V, the string select line voltage VSSL is kept at 0V and the bit line voltage VBL is kept at 0V. Refer to FIG. 5C, which illustrates the channel potential waveform CT3 of the cell string 111 at the time point T3. As the pass voltage Vpass is applied to all of the cells, the electrons are supplied to the upper cells and their channel potentials are boosted by capacitive coupling. At this time, the channel potential of cell CLn is boosted according to the pass voltage Vpass while maintaining the turned-off state.

During the program inhibit operation (from the time point T3 to the time point T6), the word line voltage VWLn is increased from 8V to 24V, the pass voltage Vpass is kept at 8V, the power voltage PW is kept at 0V, the string select line voltage VSSL is kept at 0V and the bit line voltage VBL is kept at 0V. Refer to FIG. 5D, which illustrates the channel potential waveforms CT3 to CT6 of the cell string 111 from the time point T3 to the time point T6 respectively. Along with the increasing of the word line voltage VWLn, the channel potential difference PD is decreased. The transient current will flow through the cell CLn to the cell CLn+1 due to the annihilation of the electron barrier. The hot electron disturbance on the cell CLn+1 will be consequently induced.

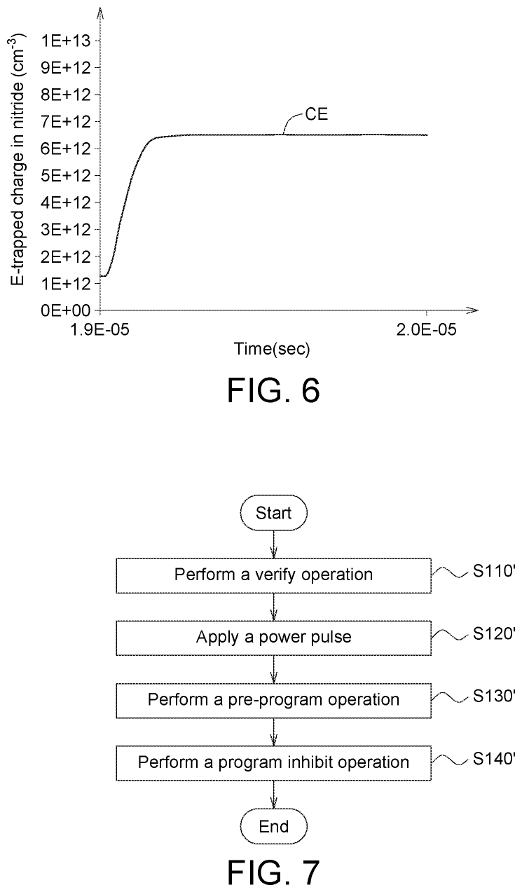

Please refer to FIG. 6 showing an E-trapped charge pattern CE of the cell CLn+1 which is injected the transient current. A hot electron signal is detected in the cell CLn+1. As shown in the E-trapped charge pattern CE, the accumulated trapped charge in nitride is increased along with the time. Therefore, the cell CLn+1 is disturbed during the program inhibit operation.

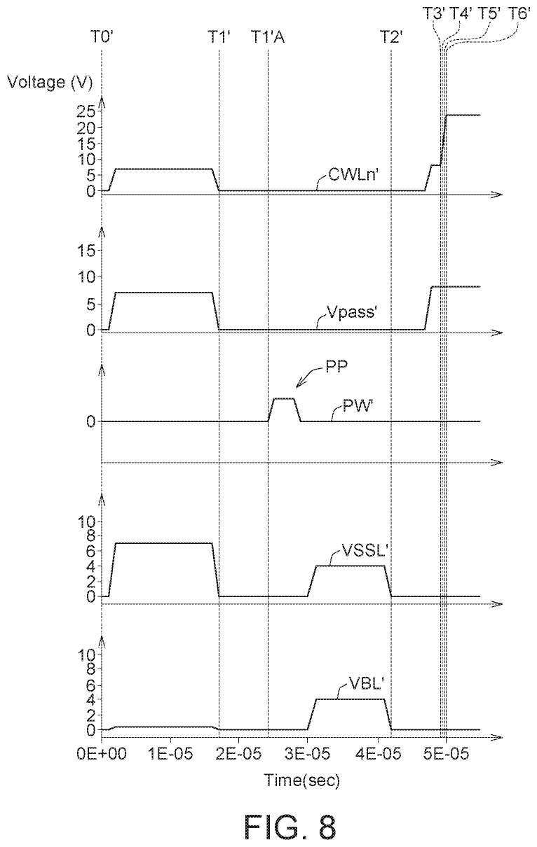

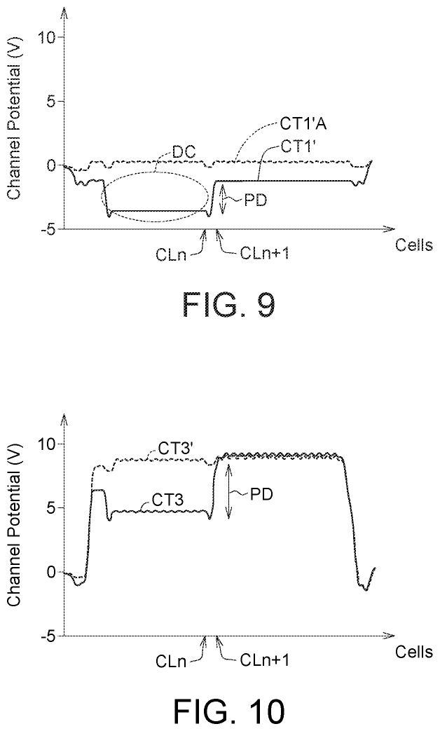

Please refer to FIG. 7 to FIG. 9. FIG. 7 shows a flowchart of a method for performing the program inhibit operation with cell disturbance alleviation, FIG. 8 illustrates the waveforms of the word line voltage VWLn′, the pass voltage Vpass′, the power voltage PW′, the string select line voltage VSSL′ and the bit line voltage VBL′, and FIG. 9 illustrates the channel potential waveforms CT1′, CT1′A in the cell string 111 at the time points T1′, T1′A respectively.

In step S110′, the controller 140 performs a verify operation on the cell string 111 from the time point T0′ to the time point T1′. In the verify operation, the word line voltage VWLn′ is increased to be 7V, the pass voltage Vpass' is increased to be 7V, the power voltage PW′ is kept at 0V, the string select line voltage VSSL′ is increased to be 7V and the bit line voltage VBL′ is increased to be 0.6V. Referring to FIG. 9, the channel potential waveforms CT1′ of the cell string 111 at the time point T1′ is shown. As the verify operation is just finished, the cell CLn is turned off and its channel potential falls to −4V due to the down-coupling phenomenon DC. There would be some channel potential difference PD between the cell CLn and the cell CLn+1.

Afterwards, in step S120′, the controller 140 applies a power pulse PP (shown in FIG. 8) on the cell string 111. In this step, the word line voltage VWLn′ is kept at 0V, the pass voltage Vpass' is kept at 0V, the power voltage PW′ is increased to be 0.5V to 1V, the string select line voltage VSSL′ is kept at 0V and the bit line voltage VBL′ is kept at 0V. In one embodiment, the power pulse PP is applied for 5 to 15 micro seconds and is applied to all of a plurality cells of the cell string 111. Referring to FIG. 9, the channel potential waveforms CT1′A of the cell string 111 at the time point T1′A is shown. After the power pulse PP is applied, the down-coupling phenomenon DC could be suppressed, and the channel potential difference PD between the cell CLn and the cell CLn+1 could be eliminated.

Next, in step S130′, the controller 140 performs a pre-program operation on the cell string 111. In the pre-program operation, the word line voltage VWLn′ is kept at 0V, the pass voltage Vpass' is kept at 0V, the power voltage PW is kept at 0V, the string select line voltage VSSL′ is increased to be 4V and the bit line voltage VBL′ is increased to be 4V.

In step S140′, the controller 140 performs a program inhibit operation on the cell string 111. At the beginning of the pre-program operation (time point T3′), the word line voltage VWLn′ is increased to be 8V, the pass voltage Vpass' is increased to be 8V, the power voltage PW is kept at 0V, the string select line voltage VSSL′ is kept at 0V and the bit line voltage VBL′ is kept at 0V.

Refer to FIG. 10, which illustrates a comparison between the channel potential waveform CT3′ of the cell string 111 at the time points T3′ and the channel potential waveform CT3 of the cell string 111 at the time points T3. As shown in FIG. 10, the large channel potential difference PD between the cell CLn and the cell CLn+1 would be vanished at the time point T3′.

During the program inhibit operation (from the time point T3′ to the time point T6′), the word line voltage VWLn′ is increased from 8V to 24V, the pass voltage Vpass' is kept at 8V, the power voltage PW is kept at 0V, the string select line voltage VSSL′ is kept at 0V and the bit line voltage VBL′ is kept at 0V. Because the down-coupling phenomenon DC is suppressed, the channel potential waveforms CT3′ is stable from the time point T3′ to the time point T6′ without inducing any hot electron disturbance on the cell CLm+1.

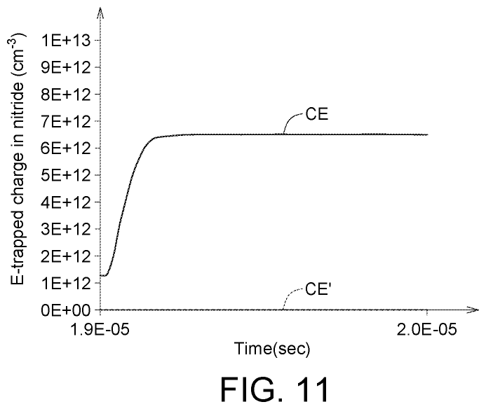

Please refer to FIG. 11, which illustrates the comparison between an E-trapped charge pattern CE′ of the cell CLn+1 which is not injected the transient current and the E-trapped charge pattern CE of FIG. 6. As shown in the E-trapped charge pattern CE′, the accumulated trapped charge in nitride is kept at low level along with the time. Therefore, the cell CLn+1 is not disturbed during the program inhibit operation.

According to the embodiment described above, the extra power pulse PP can suppress the hot electron disturbance as the word line WLn being turned on. In this embodiment, the power pulse PP is applied between the verify operation and the program inhibit operation to suppress the down-coupling phenomenon DC, and alleviate the potential risk for hot electron disturbance.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A method for performing a program inhibit operation, comprising:
performing a verify operation on a cell string of a cell array;
applying a power pulse on the cell string; and
performing the program inhibit operation on the cell string;
wherein the step of applying the power pulse is performed before the step of performing the program inhibit operation, and the power pulse is applied between the verify operation and the program inhibit operation.

2. The method according to claim 1, wherein in the step of applying the power pulse, the power pulse is applied by 0.5 to 1 V.

3. The method according to claim 1, wherein in the step of applying the power pulse, the power pulse is applied for 5 to 15 micro seconds.

4. The method according to claim 1, wherein the power pulse is applied to all of a plurality cells of the cell string.

5. The method according to claim 1, wherein the step of applying the power pulse is performed after the step of performing the verify operation.

6. The method according to claim 1, wherein the cell array is a 3D NAND memory, a floating gate memory, a nitride-trapping memory, a gate-all-around (GAA) memory or a vertical channel memory.

7. A memory device, comprising:
a cell array;
a word line decoder, connected to a plurality of word lines of the cell array;
a bit line decoder, connected to a plurality of bit lines of the cell array; and
a controller, connected to the word line decoder and the bit line decoder for performing a verify operation on a cell string of the cell array, applying a power pulse on the cell string, and performing a program inhibit operation on the cell string;
wherein the controller applies the power pulse before the program inhibit operation is performed, and the power pulse is applied between the verify operation and the program inhibit operation.

8. The memory device according to claim 7, wherein the power pulse is applied by 0.5 to 1 V.

9. The memory device according to claim 7, wherein the power pulse is applied for 5 to 15 micro seconds.

10. The memory device according to claim 7, wherein the power pulse is applied to all of a plurality cells of the cell string.

11. The memory device according to claim 7, wherein the controller applies the power pulse after the verify operation is performed.

12. The memory device according to claim 7, wherein the cell array is a 3D NAND memory, a floating gate memory, a nitride-trapping memory, a gate-all-around (GAA) memory or a vertical channel memory.

13. A controller, connected to a word line decoder and a bit line decoder, wherein the word line decoder is connected to a plurality of word lines of a cell array, the bit line decoder is connected to a plurality of bit lines of the cell array, and the controller is used for
performing a verify operation on a cell string of the cell array;
applying a power pulse on the cell string; and
performing a program inhibit operation on the cell string;
wherein the controller applies the power pulse before the program inhibit operation is performed, and the power pulse is applied between the verify operation and the program inhibit operation.

14. The controller according to claim 13, wherein the power pulse is applied by 0.5 to 1V.

15. The controller according to claim 13, wherein the power pulse is applied for 5 to 15 micro seconds.

16. The controller according to claim 13, wherein the power pulse is applied to all of a plurality cells of the cell string.

17. The controller according to claim 13, wherein the controller applies the power pulse after the verify operation is performed.

18. The controller according to claim 13, wherein the cell array is a 3D NAND memory, a floating gate memory, a nitride-trapping memory, a gate-all-around (GAA) memory or a vertical channel memory.
